(19) United States
(12) Patent Application Publication
(10) Pub. No.: US 2007/0152309 A1
(43) Pub. Date: Jul. 5, 2007

(54) Light emitting diode

(75) Inventor: Wei-Tai Cheng, Guiren Shiang (TW)

Correspondence Address: TROXELL LAW OFFICE PLLC, SUITE 1404, 5205 LEESBURG PIKE, FALLS CHURCH, VA, 22041, US

(73) Assignee: Para Light Electronics Co., Ltd.

(21) Appl. No.: 11/319,649

(22) Filed: Dec. 29, 2005

(51) Int. Cl. H01L 23/495

(52) U.S. Cl. 257/676

(57) ABSTRACT

A light emitting diode comprises: at least two electrodes; a first encapsulant layer; at least a chip; and a second encapsulant layer. The electrodes are fixed by the first encapsulant layer. The chip is electrically connected to the electrodes. The chip and the electrodes are covered with the second encapsulant layer. As a result, the substrate-free, super-thin light emitting diode is completed.

### FIELD OF THE INVENTION

The present invention relates to a light emitting diode (LED) or the like, and more particularly to a substrate-free light emitting diode with significantly reduced thickness.

### BACKGROUND OF THE INVENTION

Light emitting diode is a kind of small-sized, high-efficient, solid-state light source. The light emitting diode is a semiconductor device so it has long lifetime and high stability. The light emitting diode is suitable to be various light sources, e.g. monitors' light sources, backlight plates' light sources, traffic lights, emergency guiding lights, lighting, etc.

Referring to FIG. 4, a conventional light emitting diode, which is formed by SMD (surface mount device) technology, is shown. The conventional light emitting diode includes a substrate A on which electrodes B and a trench A1 are formed. A chip C is coupled to the substrate A in the trench A1, and the chip C is further connected to the electrodes B by bonding wires D. Thereafter, the trench A1 is filled with encapsulant E so as to integrate several above-mentioned devices into a unity.

Although the conventional light emitting diode is convenient in use and its thickness can be reduced to 0.3 mm by modern packaging technology, it still has a certain thickness. For the portable electronic machines, their components' thickness should be further reduced to bring about light, thin, short, and small electronic products.

In view of the foregoing description, the present inventor makes diligent studies in providing consumers with a substrate-free light emitting diode having significantly reduced thickness according to the motive of the present invention.

### SUMMARY OF THE INVENTION

It is a main object of the present invention to provide a substrate-free light emitting diode with significantly reduced thickness.

In order to achieve this object, a light emitting diode of the present invention comprises: at least two electrodes; a first encapsulant layer; at least a chip; and a second encapsulant layer. The electrodes are fixed by the first encapsulant layer. The chip is electrically connected to the electrodes. The chip and the electrodes are covered with the second encapsulant layer. As a result, the substrate-free, super-thin light emitting diode is completed.

The aforementioned objects and advantages of the present invention will be readily clarified in the description of the preferred embodiments and the enclosed drawings of the present invention.

### BRIEF DESCRIPTION OF THE DRAWINGS

FIG. 1 is an assembled sectional view showing a first preferred embodiment of the present invention.

FIG. 2 is an assembled sectional view showing a second preferred embodiment of the present invention.

FIG. 3 is an assembled sectional view showing a third preferred embodiment of the present invention.

FIG. 4 is an assembled sectional view showing a conventional structure.

### DETAILED DESCRIPTION OF THE PREFERRED EMBODIMENT

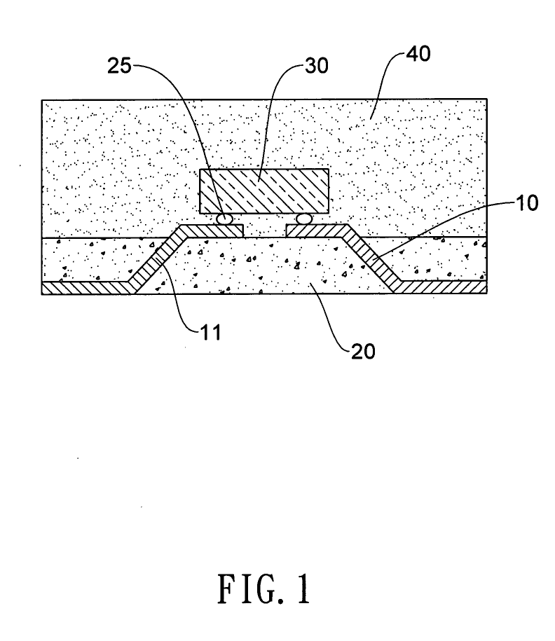

Referring to FIG. 1, a first preferred embodiment of the present invention is shown. Two electrodes 10, 11 are provided, wherein these two electrodes 10, 11 are partially covered with a first encapsulant layer 20. The first encapsulant layer 20 is, for example, PI or SU8. A chip 30 is flip-chip bonded to these two electrodes 10, 11 on exposed portions where they are not covered with the first encapsulant layer 20 by tin solders 25. Thereafter, the exposed portions of these two electrodes 10, 11 and the chip 30 are totally covered with a second encapsulant layer 40 such that a substrate-free light emitting diode is completed.

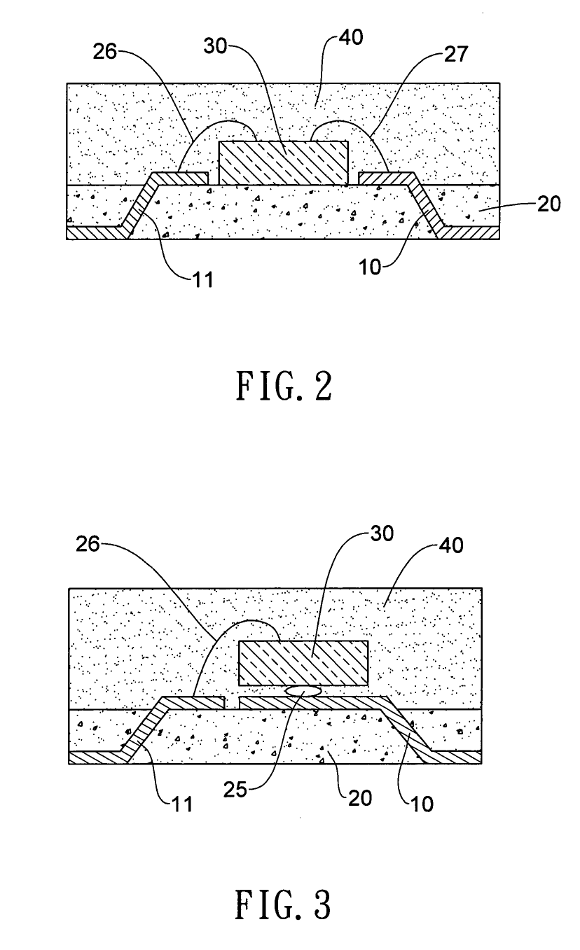

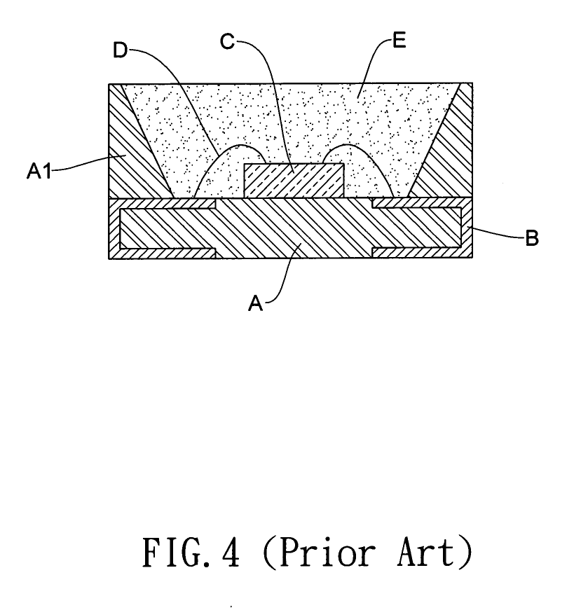

As shown in FIG. 2, these two electrodes 10, 11 are fixed by the first encapsulant layer 20, and then the chip 30 is mounted on the top of the first encapsulant layer 20. Thereafter, the chip 30 is electrically connected to these two electrodes 10, 11 by two bonding wires 26, 27. Finally, the chip 30 and these two bonding wires 26, 27 are covered with the second encapsulant layer 40 such that a substrate-free, super-thin light emitting diode is completed.

As shown in FIG. 3, these two electrodes 10, 11 have unequal lengths. Similarly, these two electrodes 10, 11 are fixed by the first encapsulant layer 20, and the chip 30 is flip-chip bonded to the top of the electrode 10 by the tin solder 25. Besides, the chip 30 is electrically connected to the electrode 11 by the bonding wire 26. Thereafter, the chip 30 and the bonding wire 26 are covered with the second encapsulant layer 40 such that a substrate-free, super-thin light emitting diode is completed.

Moreover, the first encapsulant layer 20 shown in FIG. 1, FIG. 2, and FIG. 3 is, for example, poly methylmethacrylate (PMMA), poly dimethylsioxane (PDMS), poly carbonate (PC), polyimide (PI), epoxy resin (SU-8), spin on glass (SOG), silicon gel, or resin. Besides, the second encapsulant layer 40 is, for example, silicon gel, resin, a mixture of silicon gel and fluorescent powders, or a mixture of resin and fluorescent powders.

In summary, the light emitting diode of the present invention is substrate-free and has significantly reduced thickness. Accordingly, the present invention satisfies patentability and is submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A light emitting diode comprising:
at least two electrodes;
a first encapsulant layer for fixing the electrodes;
at least a chip electrically connected to the electrodes; and
a second encapsulant layer for covering the chip and the electrodes such that the substrate-free, super-thin light emitting diode is completed.

2. The light emitting diode of claim 1, wherein the chip is electrically connected to the electrodes by a wire-bonding method.

3. The light emitting diode of claim 1, wherein the chip is electrically connected to the electrodes by a flip-chip mounting method.

4. The light emitting diode of claim 1, wherein the chip is electrically connected to the electrodes by a wire-bonding method and a flip-chip mounting method, respectively.

5. The light emitting diode of claim 1, wherein the first encapsulant layer is poly methylmethacrylate (PMMA), poly dimethylsioxane (PDMS), poly carbonate (PC), polyimide (PI), epoxy resin (SU-8), spin on glass (SOG), silicon gel, or resin.

6. The light emitting diode of claim 1, wherein the second encapsulant layer is silicon gel.

7. The light emitting diode of claim 6, wherein the second encapsulant layer is doped with fluorescent powders.

8. The light emitting diode of claim 1, wherein the second encapsulant layer is resin.

9. The light emitting diode of claim 8, wherein the second encapsulant layer is doped with fluorescent powders.
